(19) United States
(12) Patent Application Publication
(10) Pub. No.: US 2003/0152143 A1
(43) Pub. Date: Aug. 14, 2003

(54) Method of equalization by data segmentation

(76) Inventor: Pierre Andre Laurent, Bessancourt (FR)

Correspondence Address: LOWE HAUPTMAN GILMAN & BERNER, LLP, 1700 DIAGNOSTIC ROAD, SUITE 300, ALEXANDRIA, VA, 22314, US

(21) Appl. No.: 10/301,821

(22) Filed: Nov. 22, 2002

(30) Foreign Application Priority Data
Nov. 23, 2001 (FR) 01 15188

(51) Int. Cl. H03K 5/159; H03H 7/30

(52) U.S. Cl. 375/229

(57) ABSTRACT

A method and device for the equalization of data in a receiver, the data having traveled through a transmission channel, the received signal comprising one or more frames. The method determines at least one fictitious probe in the data block by using at least one part of the probes available in the frames before and after the frame considered. It also comprises a step for determining the intermediate impulse response associated with the fictitious probe or probes and the combination of said intermediate impulse responses.

### BACKGROUND OF THE INVENTION

1. Field of the Invention

The present invention relates to a method and equalizer adapted especially to serial type modems.

It can be applied for example to the equalization and demodulation, in certain serial type modems used in the HF range, of large-sized data blocks with small reference sequences positioned on either side of them.

2. Description of the Prior Art

Certain international standardization documents for the transmission methods such as the STANAG (Standardization NATO Agreement) describe waveforms, to be used for modems (modulators/demodulators), that are designed to be transmitted on serial-type narrow channels (3 kHz in general). The symbols are transmitted sequentially at a generally constant modulation speed of 2400 bauds.

Since the transmission channel used (in the HF range of 3 to 30 MHz) is particularly disturbed and since its transfer function changes relatively quickly, all these waveforms have known signals at regular intervals. These signals serve as references and the transfer function of the channel is deduced from them. Among the different standardized formats chosen, some relate to high-bit-rate modems, working typically at bit rates of 3200 to 9600 bits/s which are sensitive to channel estimation errors.

To obtain a high bit rate, it is furthermore indispensable to use a complex multiple-state QAM (Quadrature Amplitude Modulation) type modulation, and limit the proportion of reference signals to the greatest possible extent so as to maximize the useful bit rate. In other words, the communication will comprise relatively large-sized data blocks between which small-sized reference signals will be inserted.

FIG. 1 shows an exemplary structure of a signal described in the STANAG 4539 in which 256-symbol data blocks alternate with inserted, known 31-symbol blocks (called probes or references), corresponding to about 11% of the total.

To assess the impulse response h(t) of the channel at the nth data blocks, there is a first probe (n−1) located before the data block and a second probe (n) positioned after the data block, enabling an assessment of the transfer function of the channel through the combined impulse response obtained by the convolution of:

the impulse response of the transmitter, which is fixed,

the impulse response of the channel, which is highly variable,

the impulse response of the receiver, which is fixed,

these three elements coming into play to define the signal received at each point in time.

To simplify the description, it will be assumed hereinafter that this set forms the impulse response of the channel.

The DFE (Decision Feedback Equalizer) is commonly used in modems corresponding for example to STANAGs (such as the 4285) where the proportion of reference signals is relatively high and the data blocks are relatively short (for example 32 symbols in the 4285).

Another prior art method uses an algorithm known as the “BDFE” (Block Decision Feedback Equalizer) algorithm. This method amounts to estimating the impulse response of the channel before and after a data block and finding the most likely values of symbols sent (data sent) that will minimize the mean square error between the received signal and the signal estimated from a local impulse response that is assumed to be known.

This algorithm, shown in a schematic view with reference to FIG. 2, consist especially in executing the following steps:

a) estimating the impulse response of the channel having a length of L symbols, it being known that this impulse response is estimated,

b) at the beginning of the data block n comprising N useful symbols, eliminating the influence of the symbols of the probe (n−1) placed before (L−1 first symbols),

c) from the probe (n) placed after the data block, eliminating the participation of the symbols of the probe that are disturbed by the influence of the last data symbols (L−1 symbols),

d) from the sample thus obtained, whose number is slightly greater than the number of data symbols (namely N+L−1), making the best possible estimation of the value of the N useful symbols most probably sent.

The step b) may consider the impulse response of the channel to be equal to h₀(t) in the probe before the data block.

Similarly, the step c) considers the impulse response of the channel to be equal to h₁ (t) in the probe after the data block.

It can also be assumed that the impulse response of the channel evolves linearly between h₀(t) and h₁(t) all along the data block.

However, unless we use an error correction method that is sophisticated and therefore calls for high computation power, the performance characteristics obtained by means of this algorithm are hardly satisfactory for highly disturbed transmission channels, which vary at very high speed.

Conversely, it turns out that the deterioration of the performance characteristics as compared with the ideal case in which the impulse response of the channel is perfectly known, becomes substantial when the transmission channel is on the stable side or varies slowly. This arises out of the fact that it is necessary to estimate the impulse response of the channel having a length that is far too great as compared with what it is in conditions of low severity. This lowers the quality of the over-estimation which is done on the basis of the short-length probes.

In particular, for a channel with only one path, a very low value of L (a few symbols at 2400 bauds) is more than enough and leads to performance characteristics close to what they would have been with an ideal estimation of the channel.

Similarly, for a channel that varies slowly and has what is called a “low Doppler spread”, it should be possible to have a better estimation since, between neighboring blocks, the response of the channel is highly correlated (namely, it varies little) and in this case, it is possible to envisage a form of smoothing that would improve the performance characteristics.

In general, the BDFE algorithms used in the prior art have certain weaknesses, especially:

the impulse response is supposed to evolve linearly all along a data block; this is particularly less likely to occur as the Doppler spread of at least one path is not negligible. This is especially relevant for the free data blocks spaced out by a duration close to the inverse of the sampling frequency known as the Nyquist frequency, which is needed to make it possible, in theory, to know the channel perfectly,

at low values of the signal-to-noise ratio, the poor estimation of the impulse response of the channel lowers performance a little more.

### SUMMARY OF THE INVENTION

The invention relates to a method that can be used especially to adapt to the speed of the evolution of the channel and thus to have an optimum level of performance at all times while only negligibly increasing the computation power requirement.

The method and the device according to the invention are designed especially to obtain a finer and more frequent estimation of the impulse response of the channel in taking account of its speed of variation and of the level.

The description will make use of certain notations adopted, including the following:

eₙ: complex samples sent, spaced out by a symbol and belonging to one of the constellations mentioned further above (known or unknown),

rₙ: complex samples received: the values of n shall be explained each time and these samples may possible belong to a probe or to data,

L: length of the impulse response, in symbols, of the channel to be estimated,

P: the number of symbols of a probe,

N: the number of symbols of a data block,

d₀ . . . d_{P-1}: the known complex values of the reference symbols, whatever the probe concerned.

The invention relates to a method for the equalization of data in a receiver after transmission in a channel, the received signal comprising one or more frames, a frame comprising at least one probe and one data block, wherein the method comprises at least one step in which at least one fictitious probe is determined in the data block by using at least one part of the probes available in the frames before and after the frame considered, a step for determining the intermediate impulse response associated with the fictitious probe or probes and the combination of said intermediate impulse responses.

The fictitious probe is positioned for example substantially in the middle of a data block.

Several fictitious probes are positioned for example so as to be equally distributed in the data block or distributed so as to simplify the computations.

For the computation of the fictitious probes, it is possible to use a total of M probes available in the vicinity of the data block considered with M preferably as an even number.

The impulse responses associated with the fictitious probes are estimated for example by using the least error squares method.

The fictitious probes to be positioned in the data block can be determined by using interpolators and on the basis of one or more probes available before and/or after the data block.

The coefficients of the interpolators are, for example, chosen by minimizing the mean square error of the interpolation for a given maximum rotation of the impulse response between probes and for a signal-to-noise ratio value.

The coefficients of the interpolators can be determined for several values of phase rotation A.

The invention also relates to a device to equalize at least one signal that has traveled through a transmission channel, the receiver signal comprising one or more frames, a frame comprising at least one data block between two probes, the device comprises at least one means receiving the signals and adapted to determining at least one fictitious probe in the data block by using at least one part of the available probes in the frames before and after the frame considered and a device adapted to determining the intermediate impulse response associated with the fictitious probe or probes is and to combining said intermediate impulse responses.

The object of the present invention offers especially the following advantages:

it makes it possible to attain the necessary performance levels especially in the case of highly disturbed transmission channels with fast variations while only negligibly increasing the necessary computation power; and

it provides an improved estimation of the impulse response in time of the channel, leading to an increase in the performance characteristics usually obtained at low signal-to-noise ratios.

### BRIEF DESCRIPTION OF THE DRAWINGS

The present invention will be understood more clearly from the following description of an exemplary embodiment given by way of an illustration that in no way restricts the scope of the invention, and made with reference to the appended figures of which:

FIG. 1 provides a general example of the structure of the data to be transmitted,

FIG. 2 is a diagram of the BDFE algorithm used in the prior art,

FIG. 3 exemplifies an implementation of the BDFE segmentation method according to the invention,

FIG. 4 exemplifies a data block modified according to the invention,

FIG. 5 is a block diagram of the steps used to estimate the impulse response of the channel,

FIG. 6 shows several interpolators as a function of different values of phase rotation,

FIG. 7 is an exemplary functional diagram of a device according to the invention.

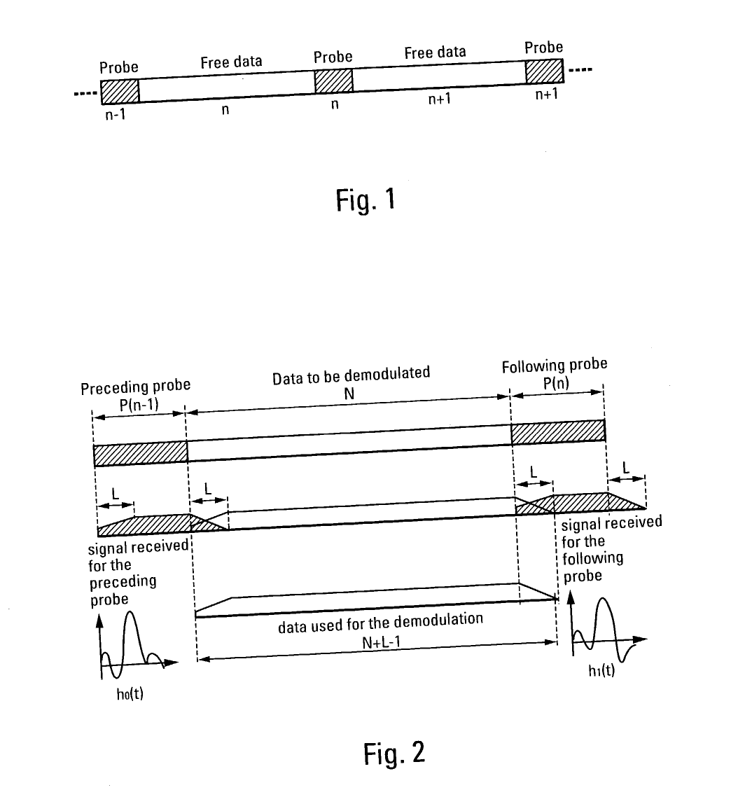

### MORE DETAILED DESCRIPTION

The example given here below by way of an illustration that is in no way restrictive relates to a signal structured in the form of super-frames comprising several frames, each frame being constituted for example by a probe or reference sequence and a data block. The frames succeed one another, thus forming a set that comprises probes preceding a data block, the data block n itself and probes following the data block. The term “current frame” hereinafter designates the frame comprising the data block to be demodulated.

In short, the method is based on the following idea: the interpolation of the impulse responses of the channel consists in computing K probes of fictitious impulse responses for example evenly spaced out in the current frame to be demodulated.

In a more general and complete way, the method according to the invention implements the following steps:

estimating the impulse response at several instants, for example evenly spaced out instants preceding a data block (hₖ₀ . . . h₀) and at several evenly spaced out instants following the data block (h₁ . . . hₖ₁), the number of these instants in which there are known signals called probes being M; this amounts to considering fictitious probes transmitted at regular intervals instead of unknown data,

re-estimating the impulse response of the channel, by interpolation/filtering, just before and just after said block to replace the initial estimation (h₀ and h₁),

estimating K intermediate impulse responses, evenly spaced out in the data block, by interpolation/filtering,

modifying the BDFE algorithm so that it takes account of the estimation “by segments” of the impulse response thus obtained,

for the smoothing operation, using filters/interpolators as closely adapted as possible to the speed of variation of the channel (its “Doppler spread”), to the signal-to-noise ratio at which it is desired to function as well as to the position (start, middle, end” in the super-frame being received,

making a choice, at regular intervals, between the available sets of interpolators on the basis of a criterion of quality which is the estimated signal-to-noise ratio resulting from the BDFE algorithm.

The system can thus be adapted at each instant to the characteristics of the transmission channel. This leads to an optimum level of performance for a small increase in the computation power.

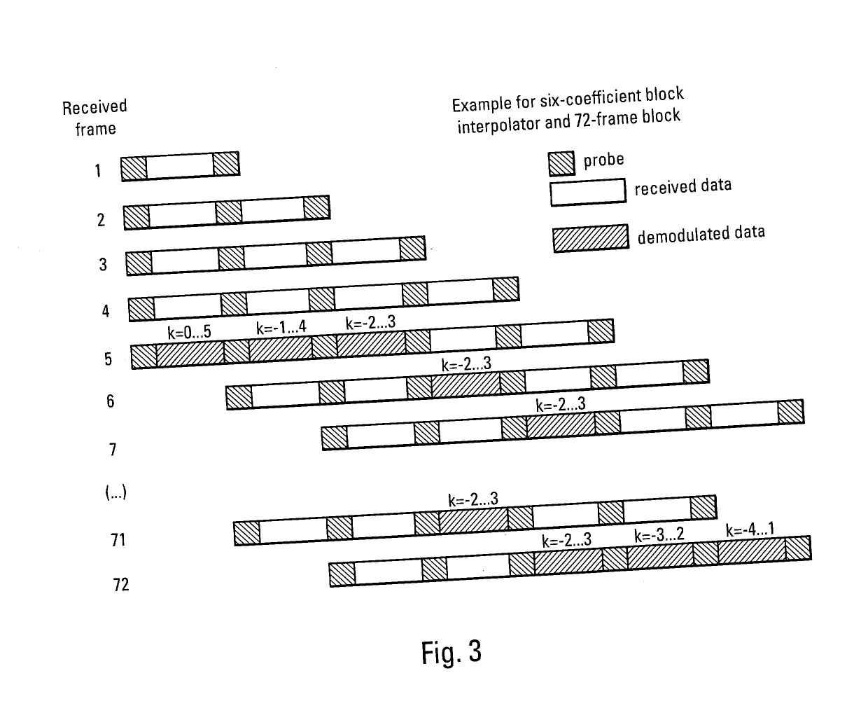

FIG. 3 gives a brief description of the interpolations to be made and the probes used, for the modem described by the document STANAG 4539 in which the frames are grouped in blocks (super-frames) of 72 frames.

In practice, and this is one of the original features of the invention, this processing operation will use not two probes (as in the prior art) but M successive probes, preferably with M as an even number, with the following convention:

the probe corresponding to the index k=0 is the probe just before the current frame,

the probe corresponding to the index k=1 is the probe just after the current frame,

the probe corresponding to the index k₀=2−M . . . 0 (k₀ always negative or zero) is the oldest probe (or the first probe available),

the probe corresponding to the index k₁=1 . . . k₀+M−1 (k₁ is always positive, greater than or equal to 1) is the most recent probe (or the most recent probe available).

In the central part of a block of frames, the probes used for the interpolation are the probes k₀=−M/2, . . . , 0, 1, . . . k₁=M/2−1. For example, for M=6, the probes used bear the numbers −2 to +3.

During the reception of the frames 1 to 4, no demodulation is done.

After reception of “(the probe after)” the frame 5, the frames 1 to 3 are demodulated by using the six available probes (from before the frame 1 till after the frame 5) with k₀=0 . . . −2 and k₁=k₀+5.

After reception of the “(probe after)” the frames t=6 . . . 71, the frames t=4 . . . 69 are demodulated by using the six probes on either side of them (3 before, 3 after), with k₀=−2 et k₁=3.

Finally, after reception of “(the probe after)” the frame 72, the frames 70 to 72 by using the last six probes received with k₀=−2 . . . −4 et k₁=k₀+5.

After reception of “(the probe after)” the frame t=6 . . . 71, the frame t=4 . . . 69 is demodulated by using the six probes on either side of it (3 before, 3 after).

Finally, after reception of “(the probe after)” the frame 72, the frames 70 to 72 are demodulated by using the last six probes received.

It can be seen that, at the beginning of the super-frame as well as at its end, the number of frames available before the current frame is not the same as the number available after it. This means that there are non-constant sets of values (k₀, k₁). It is therefore necessary to have, in all, for interpolators comprising M elements, M−1 sets of coefficients, including one symmetrical set (the one used most frequently) while the others are dissymmetrical but may, if necessary, correspond in sets of two.

This may be extended to a number M which is any number whatsoever of probes used for the filtering, this number being preferably an even number, both for reasons of simplicity (the symmetry of the coefficients of the filters) and because, in this way, the constraint according to which a stable channel must be perfectly interpolated has relatively little influence on the gain in signal-to-noise ratio (the interpolation error shows a “natural” minimum for a zero phase rotation).

### Mechanism for the Interpolation of the Impulse Responses

The interpolation proper consists of the computation of K probes or fictitious impulse responses evenly spaced out in the current frame to be demodulated. At the end of this interpolation step, the method has K fictitious intermediate impulse responses available. These will be used to estimate the impulse response of the propagation channel before implementing a BDFE algorithm.

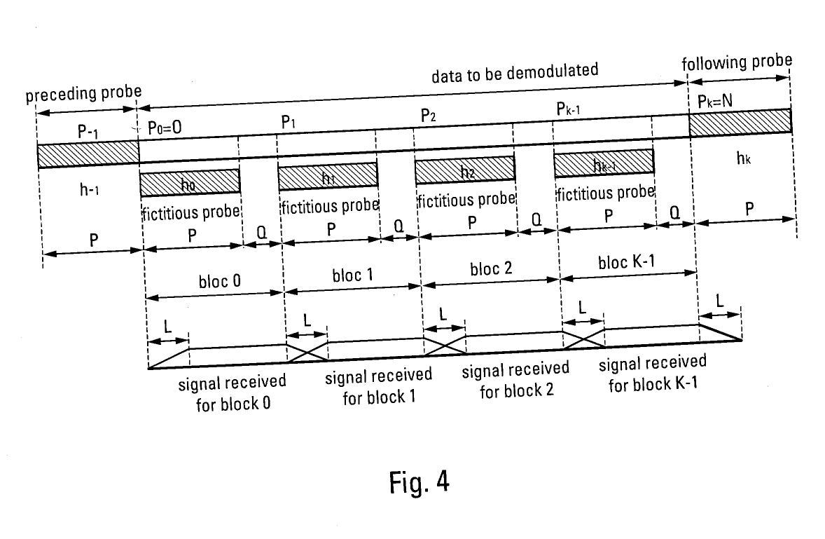

FIG. 4 gives a schematic view of an exemplary distribution of fictitious probes inside a data block to be demodulated. In this example, the data block is chopped up into K sub-blocks, for example, or sub-blocks of equal of substantially equal length. The selected number of sub-blocks K must preferably divide the number N of symbols in the data block for reasons of simplicity. It is also possible not to meet this constraint. Each index i sub-block is associated with an impulse response hi defined at its start by a fictitious probe Pi with a length P. The reference Q designates the length corresponding to the data of a sub-block between the fictitious probe Pi of this block and the fictitious probe after Pi+1.

This drawing also shows the signal received for a given index I block, taking account of the length L of the response of the transmission channel.

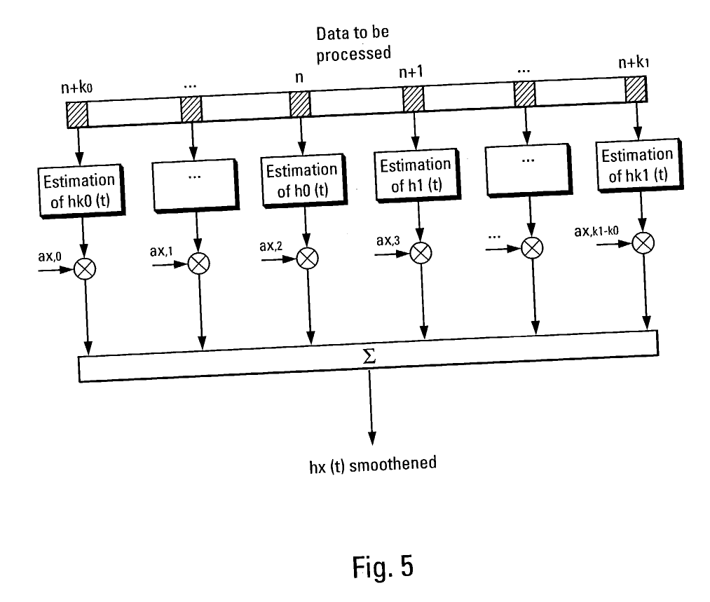

The interpolation of the fictitious probes is made according to a diagram shown in FIG. 5, for example. The reference x defines the position of the probe concerned, using a convention according to which x=0 corresponds to the real probe before the data block considered, namely the data block to be demodulated, and x=1 corresponds to the real probe after this data block.

In this example, the values of the positions x for the intermediate fictitious probes associated with the data block are for example the following, k being the rank of the probe in the data elements:

k=:x=P/(P+N)

k=1:x=(P+(P+Q))/(P+N)ou(P+N/K)/(P+N)

k=2:x=(P+2(P+Q))/(P+N)ou(P+2N/K)/(P+N) . . .

k=K−1:x=(P+(K−1)(P+Q))/(P+N)ou(P+(K−1)N/K)/(P+N)

with P, N and Q defined here above.

In the algorithm proposed, the computation will also be performed for the true probes, namely k=−1, x=0 for the current probe, and k=K, x=1 for the next probe, to benefit from the noise reduction obtained by the interpolation, which is also optimized to ensure a filtering function (see further below).

First Step of the Method: the Estimation of the Impulse Response Associated with a Fictitious Probe Having an Index i

The first step consists in estimating the “true” impulse responses, whose number is equal to M, associated with the probes ranking n+k₀ . . . n+k₁. These impulse responses are referenced hₖ(t) or h_{k, 0 . . . L-1}, with k=k₀ . . . k₁ it being known that M=k₁−k₀+1;

These impulse responses are estimated, for example, according to the least error squares method known to those skilled in the art and recalled by way of a non-restrictive example.

A search is made for the best estimation of the L samples of the impulse response h of the channel, referenced h_{0 . . . L-1}, this method being the same for all the impulse responses, the index k of h_{k, 0 . . . L-1} is omitted. The known sent signal is d₀ . . . d_{P-1}, for a given probe and the signal to be processed is referenced r₀ . . . r_{P-1}, for this same probe.

The impulse response h is estimated by minimizing the total quadratic error given by:

$$E = {\sum }_{n = {N}_{a}}^{{N}_{1}} \vert {\sum }_{m = 0}^{L - 1} {d}_{n - m} {h}_{m} - {r}_{n} {\vert}^{2} \qquad ( 1 )$$

So that only the known symbols will come into play (i.e. d₀ to d_{P-1} only), we take N₀=L−1 and N₁=P−1. The consequence of this, in particular, is that, during the previous filtering operation, only the P−L (instead of L) corrected values r′ are computed.

The minimizing of E leads to the L following equations:

$${\sum }_{n = L - 1}^{P - 1} {d}_{n - p}^{*} ( {\sum }_{m = 0}^{L - 1} {d}_{n - m} {h}_{m} - {r}_{n} ) = 0 \qquad ( 2 )$$

$$p = 0 . . . L - 1$$

which can be rewritten as follows:

$${\sum }_{m = 0}^{L - 1} {h}_{m} ( {\sum }_{n = L - 1}^{P - 1} {d}_{n - m} {d}_{n - p}^{*} ) = {\sum }_{n = L - 1}^{P - 1} {r}_{n} {d}_{n - p}^{*} \qquad ( 3 )$$

$$p = 0 . . . L - 1$$

or again:

$${\sum }_{m = 0}^{L - 1} {A}_{p . m} {h}_{m} = {B}_{p} \qquad ( 4 )$$

$$p = 0 . . . L - 1$$

$$with$$

$${A}_{p , m} = {\sum }_{n = L - 1}^{P - 1} {d}_{n - m} {d}_{n - p}^{*} = {A}_{m , p}^{*}$$

$$\text{and}$$

$${B}_{p} = {\sum }_{n = L - 1}^{P - 1} {r}_{n} {d}_{n - p}^{*}$$

$$p = 0 . . . L - 1$$

Since the matrix A={A_{p,m}} is Hermitian, the solution to the problem is obtained by using the Cholesky decomposition L-U, well known to those skilled in the art, where A=L U and:

L is a lower triangular matrix having only ones on the diagonal,

U is a higher triangular matrix where the elements of the diagonal are real.

In practice the matrices L and U are precomputed for example in a read-only memory since the matrix A is formed out of constant values.

Formally, it can be written that Ah=B or L U h=B, which is resolved by bringing into play an intermediate vector y, in first of all resolving L y=B then U h=y.

Once the M impulse responses have been found, their linear combination is computed at a given position x, namely hx(t) where h_{x, 0 . . . L-1} by the simple equation:

$${h}_{x , i} = {\sum }_{k = {k}_{0}}^{k = {k}_{1}} {a}_{x , k - {k}_{0}} {h}_{k , i} = {\sum }_{m = 0}^{m = {k}_{1} - {k}_{0}} {a}_{x , m} {h}_{m + {k}_{0 , i}} \qquad ( 5 )$$

$$i = 0 . . . L - 1$$

this corresponds to the ith sample of the impulse response for a position x.

The M real coefficients a_{x, 0 . . . M-1} are the coefficients of an interpolator which depends on x, k₀ and k₁ and which is optimized for given conditions of transmission.

An exemplary mode of computation of optimization is explained here below.

Optimization of the Coefficients M for the Interpolators

The object of the interpolators especially is to make an estimation, on the basis of the true probes, located at the positions k₀ . . . k₁ (with respect to the current frame ), of the K probes or the K fictitious intermediate impulse responses to be used in the current frame.

The criterion chosen consists for example in minimizing the mean square error of interpolation for a given maximum rotation of the impulse response between probes (which corresponds to a given “Doppler spread”) and for a given signal-to-noise ratio (which depends on the specifications) in order to obtain a noise-reducing filtering function of the same time.

Furthermore, it is required that the interpolation should be perfect for a zero phase rotation, enabling a maximum level of performance on a channel with slow variations. Experience shows that this constraint has a minimum effect on the interpolation noise when the number M of coefficients of the interpolations is an even number because the interpolation error shows a “natural” minimum in the neighbourhood of 0 if M is an even number.

Each interpolator has M real coefficients: a_{0 . . . M-1}

To determine the coefficients, the method seeks to minimize the mean square error:

for a given noise power value β (i.e. a well-defined signal-to-noise ratio),

at a position x ranging from 0 to 1, it being known that the position 0 corresponds to the probe before, the position 1 to the probe after and the intermediate values to the fictitious probes between the two,

in using the signal at the positions k₀, . . . , 0, 1, . . . k₁=k₀+M−1,

it being known that the phase rotation between two positions is equal to A at most in terms of absolute value (A<π),

with the constraint that the interpolation should be perfect for a zero phase rotation (perfect interpolation of the continuous).

The noise power, to be minimized, is equal to:

$$B = β {\sum }_{i = 0}^{M - 1} {a}_{i}^{2} \qquad ( 6 )$$

The interpolation error for a rotation θ is equal to:

$$E ( 8 ) = \vert {\sum }_{i = 0}^{M - 1} {a}_{1} {ⅇ}^{jθ ( {k}_{0} + ⅈ )} - {ⅇ}^{j \times θ} {\vert}^{2} \qquad ( 7 )$$

The mean square error is then:

$$EQM = \frac{1}{2 A} {\int }_{- A}^{+ A} E ( 8 ) ⅆ θ + B \qquad ( 8 )$$

and its (half-)derivative with respect to aₘ (m=0 . . . M−1):

$$\frac{1}{2} \frac{δ EQM}{δ {a}_{m}} = \frac{1}{2 A} {\int }_{- A}^{+ A} {ⅇ}^{- j θ ( {k}_{0} + m )} ( {\sum }_{i = 0}^{M - 1} {a}_{1} {ⅇ}^{jθ ( {k}_{0} + i )} - {ⅇ}^{j \times θ} ) d θ + β {a}_{m} \qquad ( 9 )$$

that is:

$$\frac{1}{2} \frac{δ EQM}{δ {a}_{m}} = \frac{1}{2 A} ( {\sum }_{i = 0}^{M - 1} {a}_{i} {\int }_{- A}^{+ A} {ⅇ}^{jθ ( ⅈ - m )} ⅆ θ - {\int }_{- A}^{+ A} {ⅇ}^{j θ ( x - {k}_{0} - m )} ⅆ θ ) + {βa}_{m} \qquad ( 10 )$$

or again:

$$\frac{1}{2} \frac{δ EQM}{δ {a}_{m}} = {{\sum }_{i = 0}}^{M - 1} {a}_{i} \frac{sin ( ( i - m ) A )}{( i - m ) A} - \frac{sin ( ( x - {k}_{0} - m ) A )}{( x - {k}_{0} - m ) A} + β {a}_{m} \qquad ( 11 )$$

The constraint C is given by:

$$C = {\sum }_{i = 0}^{M - 1} {a}_{i} - 1 \qquad ( 12 )$$

The minimization with constraint will consist in minimizing the quantity:

EQM+λC (13)

with the additional equation:

C=O (14)

The final system of equations to be resolved therefore has the dimension

M+1 with M+1 unknowns, namely λ (unused) and a_{0 . . . M-1} :

M minimization equations:

$$\begin{matrix}{\sum }_{i = 0}^{M - 1} {a}_{i} \frac{sin ( ( i - m ) A )}{( i - m ) A} + β {a}_{m} + λ = \frac{sin ( ( x - {k}_{0} - m ) A )}{( x - {k}_{0} - m ) A} \\ m = O … M - 1\end{matrix} \qquad ( 15 )$$

one equation for the constraint:

$${\sum }_{i = 0}^{M - 1} {a}_{i} = 1 \qquad ( 16 )$$

The method implements, for example, the following solution: take the sum of the K first equations and deduct λ therefrom, it being known that the sum of the values aᵢ is equal to 1:

$$λ = \frac{1}{M} ( {\sum }_{j = 0}^{M - 1} \frac{sin ( ( x - {k}_{0} - j ) A )}{( x - {k}_{0} - j ) A} - {\sum }_{i = 0}^{M - 1} {a}_{i} {\sum }_{j = 0}^{M - 1} \frac{sin ( ( i - j ) A )}{( i - j ) A} - β ) \qquad ( 17 )$$

modify the M first equations:

$$\begin{matrix}{\sum }_{i = 0}^{M - 1} {a}_{i} ( M \frac{sin ( ( i - m ) A )}{( i - m ) A} - {\sum }_{j = 0}^{M - 1} \frac{sin ( ( i - j ) A )}{( i - j ) A} ) + M β {a}_{m} = \\ \begin{matrix}β + M \frac{sin ( ( x - {k}_{0} - m ) A )}{( x - {k}_{0} - m ) A} - {\sum }_{j = 0}^{M - 1} \frac{sin ( ( x - {k}_{0} - j ) A )}{( x - {k}_{0} - j ) A} \\ m = O … M - 1\end{matrix}\end{matrix} \qquad ( 18 )$$

resolve the system of M modified equations.

The interpolators are, for example, computed once and for all and are stored in a read-only memory.

According to an alternative mode of implementation of the method, sets of interpolators corresponding to different rotational values A are computed. This advantageously enables adaptation to different channels which are variably stable in time. A stable channel corresponds to a maximum rotation A close to 0.

The optimization signal-to-noise ratio will be, for example, a function of its theoretical value for a given error rate (for example 10⁻⁵). This value is all the lower as:

the constellation used is less populated (a four-state QPSK or quadrature phase shift keying is far less fragile than a QAM-64 or 64-state quadrature amplitude modulation),

the maximum phase variation A is low (A represents the Doppler spread of the channel and a low Doppler spread necessitates a lower signal-to-noise ratio than a high Doppler spread.

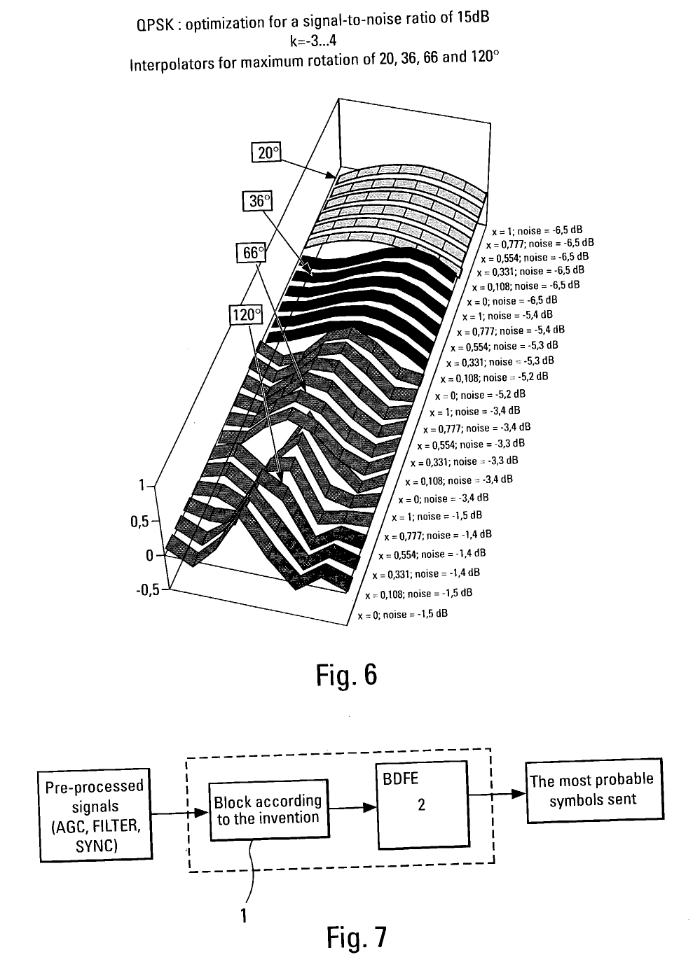

FIG. 6 shows the coefficients of the interpolators for M=8 elements, K=4 fictitious probes, and rotational values A in geometrical progression: A=A₀ . . . A₃=20°, 36°, 66° and 120°.

The values in dB give the effect of noise reduction obtained, 5 namely the ratio between the signal-to-noise ratio of the direct estimation and the signal-to-noise ratio of the interpolated estimation: the greater the bandwidth of the interpolator (expressed by the value of A), the lower is this reduction.

If we consider the method as a whole, the interpolators are advantageously chosen especially in order to follow the evolution of the transmission channel as closely as possible.

The method chooses the “optimum” set of interpolators, for example frame by frame or at least at intervals that are sufficiently close to each other to make it possible to follow the progress of the transmission channel.

If, at the previous frame (or for the previous frames), the interpolator corresponding to Aₚ has been chosen (p=0 . . . 3 in this example), the demodulation will be done with the interpolators corresponding to Aₚ₋₁ (if possible), Aₚ, and Aₚ₊₁ (if possible) and it is the one that gives the best results that will served as a starting point for the next frame (or for the following frames).

BDFE Algorithm Using Segments

The impulse responses used to execute the BDFE algorithm are, for example, the following, their number being equal to K+2:

h⁽⁻¹⁾_{0 . . . L-1}=h_{0, 0 . . . L-1} (associated with the probe before, corresponding to x=0)

h^{(0 . . . K-1)}_{0 . . . L-1}=h_{x, 0 . . . L-1} (associated with the K fictitious probes, at the positions x=x₀ . . . x_{K-1}) where x_{K} is given by:

$${x}_{κ} = \frac{P + {P}_{κ}}{P + N} \\ k = O \cdot K - 1 \\ with \\ {P}_{κ} = k \frac{N}{K} ( position of the pulse response ) \qquad ( 19 )$$

Pₖ=KN/K (position of the pulse response) (19)

h^{(K)}_{0 . . . L-1}=h_{1, 0 . . . L-1} (associated with the probe after, corresponding to x=1)

The probes considered for the current frame correspond to the symbols having the following indices:

−P . . . −1 (true probe before)

P₀ . . . P₀+P−1 (first fictitious probe)

P₁ . . . P₁+P−1 (second fictitious probe)

..............;

P_{K-1} . . . P_{K-1}+P−1 (Kth fictitious probe)

N . . . N+P−1 (true probe after)

Hereinafter, and in order to be in conformity with the diagram describing the intermediate probes, N/K shall be defined as being equal to P+Q where P is the length of the probe (true or fictitious) and Q is the length of a data segment between two fictitious probes.

Once the different impulse responses have been computed, the influence of the probes on the data is eliminated by replacing the samples received by samples corrected r^{C}ₙ as follows:

probe before (20):

$$\begin{matrix}{r}_{n}^{c} = {r}_{n} - {\sum }_{j = n + 1}^{L - 1} {d}_{P + n - j} ( {h}_{j}^{( - 1 )} + \frac{n - j - {P}_{- 1}}{{P}_{0} - {P}_{- 1}} ( {h}_{j}^{( 0 )} - {h}_{j}^{( - 1 )} ) ) = \\ \begin{matrix}{r}_{n} - \frac{1}{{P}_{0} - {P}_{- 1}} {\sum }_{j = n + 1}^{L - 1} {d}_{P + n - j} ( ( {P}_{0} - n + j ) {h}_{j}^{( - 1 )} + ( n - j - {P}_{- 1} ) {h}_{j}^{( 0 )} ) \\ \begin{matrix}n = O … L - 2 \\ reminder : {P}_{- 1} = - P\end{matrix}\end{matrix}\end{matrix}$$

at the center (21)

$$\begin{matrix}{r}_{n}^{c} = {r}_{n} \\ n = L - 1 … N - 1\end{matrix}$$

probe after (22):

$$\begin{matrix}{r}_{n}^{c} = {r}_{n} - ϵ {\sum }_{j = 0}^{n - N} {d}_{n - j - N} ( {h}_{j}^{( K - 1 )} + \frac{n - j - {P}_{K - 1}}{{P}_{K} - {P}_{K - 1}} ( {h}_{j}^{( K )} - {h}_{j}^{( K - 1 )} ) ) = \\ \begin{matrix}{r}_{n} - \frac{ϵ}{{P}_{K} - {P}_{K - 1}} {\sum }_{j = 0}^{n - N} {d}_{n - j - N} ( ( {P}_{K} - n + j ) {h}_{j}^{( K - 1 )} + ( n - j - {P}_{K - 1} ) {h}_{j}^{( K )} ) \\ \begin{matrix}n = N … N + L - 1 \\ reminder : {P}_{K} = N\end{matrix}\end{matrix}\end{matrix}$$

The symbols received then depend on no other values than on the bᵢ values.

In the ideal case, the influence of the probes has been eliminated, the received samples, referenced r^{id}ₙ are given by:

start of the block 0:

$${r}_{n}^{id} = {\sum }_{j = 0}^{j = n} {b}_{n - j} ( {h}_{j}^{( 0 )} + \frac{n - j - {P}_{0}}{{P}_{1} - {P}_{0}} ( {h}_{j}^{( 1 )} - {h}_{j}^{( 0 )} ) ) \\ {r}_{n}^{id} = \frac{1}{P + Q} {\sum }_{j = 0}^{j = n} {b}_{n - j} ( ( P + Q + j - n ) {h}_{j}^{( 0 )} + ( n - j ) {h}_{j}^{( 1 )} ) \\ {r}_{n}^{id} = \frac{1}{P + Q} {\sum }_{m = 0}^{n} {b}_{m} ( ( P + Q - m ) {h}_{n - m}^{( 0 )} + m {h}_{n - m}^{( 1 )} ) \\ n = O … L - 2 \qquad ( 23 )$$

remainder of the block 0:

$${r}_{n}^{id} = {\sum }_{j = 0}^{j = L - 1} {b}_{n - j} ( {h}_{j}^{( 0 )} + \frac{n - j - {P}_{0}}{{P}_{1} - {P}_{0}} ( {h}_{j}^{( 1 )} - {h}_{j}^{( 0 )} ) ) \\ {r}_{n}^{id} = \frac{1}{P + Q} {\sum }_{j = 0}^{j = L - 1} {b}_{n - j} ( ( P + Q + j - n ) {h}_{j}^{( 0 )} + ( n - j ) {h}_{j}^{( 1 )} ) \\ {r}_{n}^{id} = \frac{1}{P + Q} {\sum }_{m = n - L + 1}^{n} {b}_{m} ( ( P + Q - m ) {h}_{n - m}^{( 0 )} + m {h}_{n - m}^{( 1 )} ) \\ n = L - 1 … P + Q - 1 \qquad ( 24 )$$

start of the block k, including the trailing of the block k−1 (k=1 . . . K−1):

$${r}_{n}^{id} = {\sum }_{j = n - k ( P + Q ) + 1}^{L - 1} {b}_{n - j} ( {h}_{j}^{( k - 1 )} + \frac{n - j - {P}_{k - 1}}{{P}_{k} - {P}_{k - 1}} ( {h}_{j}^{( k )} - {h}_{j}^{( k - 1 )} ) ) + {\sum }_{j = 0}^{j = n - k ( P + Q )} {b}_{n - j} ( {h}_{j}^{( k )} + \frac{n - j - {P}_{k}}{{P}_{k + 1} - {P}_{k}} ( {h}_{j}^{( k + 1 )} - {h}_{j}^{( k )} ) ) \\ {r}_{n}^{id} = \frac{1}{P + Q} ( \begin{matrix}{\sum }_{j = n - k ( P + Q ) + 1}^{L - 1} {b}_{n - j} ( ( k ( P + Q ) + j - n ) {h}_{j}^{( k - 1 )} + ( n - j - ( k - 1 ) ( P + Q ) ) {h}_{j}^{( k )} ) + \\ {\sum }_{j = 0}^{j = n - k ( P + Q )} {b}_{n - j} ( ( ( k + 1 ) ( P + Q ) + j - n ) {h}_{j}^{( k )} + ( n - j - k ( P + Q ) ) {h}_{j}^{( k + 1 )} )\end{matrix} ) \\ {r}_{n}^{id} = \frac{1}{P + Q} ( \begin{matrix}{\sum }_{m = n - L + 1}^{k ( P + Q ) - 1} {b}_{m} ( ( k ( P + Q ) - m ) {h}_{n - m}^{( k - 1 )} + ( m - ( k - 1 ) ( P + Q ) ) {h}_{n - m}^{( k )} ) + \\ {\sum }_{m = k ( P + Q )}^{n} {b}_{m} ( ( ( k + 1 ) ( P + Q ) - m ) {h}_{n - m}^{( k )} + ( m - k ( P + Q ) ) {h}_{n - m}^{( k + 1 )} )\end{matrix} ) \\ n = k ( P + Q ) … k ( P + Q ) + L - 2 \qquad ( 25 )$$

remainder of the block k (k=1 . . . K−1):

$${r}_{n}^{id} = {\sum }_{j = 0}^{j = L - 1} {b}_{n - j} ( {h}_{j}^{( k )} + \frac{n - j - {P}_{k}}{{P}_{k + 1} - {P}_{k}} ( {h}_{j}^{( k + 1 )} - {h}_{j}^{( k )} ) ) \\ {r}_{n}^{id} = \frac{1}{P + Q} {\sum }_{j = 0}^{j = L - 1} {b}_{n - j} ( ( ( k + 1 ) ( P + Q ) + j - n ) {h}_{j}^{( k )} + ( n - j - k ( P + Q ) ) {h}_{j}^{( k + 1 )} ) \\ {r}_{n}^{id} = \frac{1}{P + Q} {\sum }_{m = n - L + 1}^{n} {b}_{m} ( ( ( k + 1 ) ( P + Q ) - m ) {h}_{n - m}^{( k )} + ( m - k ( P + Q ) ) {h}_{n - m}^{( k + 1 )} ) \\ n = k ( P + Q ) + L - 1 … ( k + 1 ) ( P + Q ) - 1 \qquad ( 26 )$$

trailing of the block K−1:

$${r}_{n}^{id} = {\sum }_{j = n - N + 1}^{L - 1} {b}_{n - j} ( {h}_{j}^{( K - 1 )} + \frac{n - j - {P}_{K - 1}}{{P}_{K} - {P}_{K - 1}} ( {h}_{j}^{( K )} - {h}_{j}^{( K - 1 )} ) ) \\ {r}_{n}^{id} = \frac{1}{P + Q} {\sum }_{j = n - N + 1}^{L - 1} {b}_{n - j} ( ( N + j - n ) {h}_{j}^{( K - 1 )} + ( n - j - ( N - ( P + Q ) ) ) {h}_{j}^{( K )} ) \\ {r}_{n}^{id} = \frac{1}{P + Q} {\sum }_{m = n - L + 1}^{N - 1} {b}_{m} ( ( N - m ) {h}_{n - m}^{( K - 1 )} + ( m - ( N - ( P + Q ) ) ) {h}_{n - m}^{( K )} ) \\ n = N … N + L - 2 \qquad ( 27 )$$

The computation of the bᵢ values is done, for example, by minimizing the quantity:

$${E}_{r} = {\sum }_{n = 0}^{N + L - 2} \vert {r}_{n}^{id} - {r}_{n}^{c} {\vert}^{2} \qquad ( 28 )$$

it being known that bₘ (m=0 . . . N−1) comes into play only in the computation of L “ideal” samples, those having indices m, m+1, . . . , m+L−1.

In a rigorous way, it is verified that (29):

bₖ(P+Q)+i

with

k=0 . . . K−1

i=0 . . . P+Q−1

appears in

rₖ^{id}(P+Q)+i+j

with

j=0 L−1

with a coefficient equal to

$${β}_{k , i , j} = \frac{( P + Q - i ) {h}_{j}^{( k )} + i {h}_{j}^{( k + 1 )}}{P + Q \\ k = O … K - 1 \\ i = O … P + Q - 1 \\ j = O … L - 1}$$

The N equations used to determine the bₘ values will result from the cancellation of the N following derivatives (30):

$$\begin{matrix}\frac{\partial {E}_{r}}{\partial {b}_{m}^{*}} = {\sum }_{n = 0}^{N + L - 2} \frac{\partial {r}_{n}^{id}}{\partial {b}_{m}^{*}} ( {r}_{n}^{id} - {r}_{n}^{c} ) \\ = {\sum }_{n = m}^{m + L - 1} \frac{\partial {r}_{n}^{id}}{\partial {b}_{m}^{*}} ( {r}_{n}^{id} - {r}_{n}^{c} ) \\ m = O … N - 1\end{matrix}$$

or again:

$$\frac{\partial {E}_{r}}{\partial {b}_{k}^{*} ( P + Q ) + i} = {\sum }_{j = 0}^{L - 1} {β}_{k , i , j}^{*} ( {r}_{k}^{id} ( P + Q ) + i + j - {r}_{k}^{c} ( P + Q ) + i + j ) \\ k = O … k - 1 \\ i = O … P + Q - 1 \qquad ( 31 )$$

or again:

$$Input Workspace TL4 \\ Date : 08 / 14 / 2003 Number : 10301821 Folder : 05$$

The N equations to be resolved will therefore have the form:

$$\begin{matrix}{\sum }_{j = 0}^{L - 1} {β}_{k , i , j}^{*} {r}_{m + j}^{id} = {\sum }_{j = 0}^{L - 1} {β}_{k , i , j}^{*} {r}_{m + j}^{c} \\ \begin{matrix}k = O … K - 1 \\ i = O … P + Q - 1 \\ m = k ( P + Q ) + i\end{matrix}\end{matrix} \qquad ( 33 )$$

The second member is computed as follows:

$$\begin{matrix}{D}_{m} = {\sum }_{j = 0}^{L - 1} {β}_{k , i , j}^{*} {r}_{m + j}^{c} = \frac{1}{P + Q} {\sum }_{j = 0}^{L - 1} ( ( P + Q - i ) {h}_{j}^{( k ) *} + i {h}_{j}^{( k + 1 ) *} ) {r}_{m + j}^{c} \\ k = O … K - 1 \\ i = O … P + Q - 1 \\ m = k ( P + Q ) + i\end{matrix} \qquad ( 34 )$$

The first member is obtained, for example, by taking up the equations giving the r_{id} values and clarifying them by using the coefficients β_{k,i,j} defined further above:

$$\begin{matrix}{r}_{n}^{id} = {\sum }_{m = 0 \\ n = O … L - 2}^{n} {b}_{m} {β}_{O , m , n - m} & ( 35 ) \\ {r}_{n}^{id} = {\sum }_{m = n - L + 1 \\ n = L - 1 … P + Q - 1}^{n} {b}_{m} {β}_{O , m , n - m} \\ for k = 1 … K - 1 : & ( 36 ) \\ {r}_{n}^{id} = {\sum }_{m = n - L + 1}^{k ( P + Q ) - 1} {b}_{m} {β}_{k - 1 , m - ( k - 1 ) ( P + Q ) , n - m} + {\sum }_{m = k ( P + Q )}^{n} {b}_{m} {β}_{k , m - k ( P + Q ) , n - m} \\ n = k ( P + Q ) … k ( P + Q ) + L - 2 \\ for k = 1 … K - 1 : & ( 37 ) \\ {r}_{n}^{id} = {\sum }_{m = n - L + 1 \\ n = k ( P + Q ) + L - 1 … ( k + 1 ) ( P + Q ) - 1}^{n} {b}_{m} {β}_{k , m - k ( P + Q ) , n - m} & ( 38 ) \\ {r}_{n}^{id} = {\sum }_{m = n - L + 1 \\ n = N \cdot N + L - 2}^{N - 1} {b}_{m} {β}_{K - 1 , m - ( N - ( P + Q ) ) , n - m} & ( 39 )\end{matrix}$$

In considering, in the m=k (P+Q)+i ranking equation, for k=0 . . . K−1, and i=0 . . . P+Q−1, the coefficient of bₘ₊ₚ (with p=0 . . . L−1, because the corresponding matrix is Hermitian, and contains only zeros at a distance greater than or equal to L from its diagonal) is given by (40):

$$\text{-} for i = 0 … P + Q - L and p = 0 … L - 1 : \\ {\sum }_{q = 0}^{L - 1 - p} {β}_{k , i , q + p}^{*} {β}_{k , i + p , q}$$

$$\text{-} for i = P + Q - L + 1 … P + Q - 1 et k = 0 … K - 2 : \\ \text{-} for p = 0 … P + Q - 1 - i : \\ {\sum }_{q = 0}^{L - 1 - p} {β}_{k , i , q + p}^{*} {β}_{k , i + p , q}$$

$$\text{-} for p = P + Q - i … L - 1 : \\ {\sum }_{q = 0}^{L - 1 - p} {β}_{k , i , q + p}^{*} {β}_{k + 1 , i + p - P - Q , q}$$

$$\text{-} for i = P + Q - L + 1 … P + Q - 1 et K - 1 : \\ \text{-} for p = 0 … P + Q - 1 - i : \\ {\sum }_{q = 0}^{L - 1 - p} {β}_{k , i , q + p}^{*} {β}_{k , i + p , q}$$

$$\text{-} for p = P + Q - i … L - 1 : \\ \begin{matrix}0 ( zero , for if the corresponding \\ values bi do not exist … )\end{matrix}$$

$$The following expression ( 41 ) : \\ {\sum }_{q = 0}^{L - 1 - p} {β}_{k , i , q + p}^{*} {β}_{k , i + p , q}$$

develops successively into:

$$\frac{1}{{( P + Q )}^{2}} {\sum }_{q = 0}^{L - 1 - p} ( ( P + Q - i ) {h}_{q + p}^{( k ) *} + i {h}_{q + p}^{( k + 1 ) *} ) ( ( P + Q - i - p ) {h}_{q}^{( k )} + ( 1 + p ) {h}_{q}^{( k + 1 )} )$$

$$\frac{1}{{( P + Q )}^{2}} {\sum }_{q = 0}^{L - 1 - p} ( ( P + Q ) {h}_{q + p}^{( k ) *} + i ( {h}_{q + p}^{( k + 1 ) *} - {h}_{q + p}^{( k ) *} ) ) ( ( P + Q - p ) {h}_{q}^{( k )} + p {h}_{q}^{( k + 1 )} + i ( {h}_{q}^{( k + 1 )} - {h}_{q}^{( k )} ) )$$

$$\frac{1}{{( P + Q )}^{2}} ( \begin{matrix}{\sum }_{q = 0}^{L - 1 - p} ( P + Q ) {h}_{q + p}^{( k ) *} ( ( P + Q - p ) {h}_{q}^{( k )} + p {h}_{q}^{( k + 1 )} ) + \\ \begin{matrix}i {\sum }_{q = 0}^{L - 1 - p} ( P + Q ) {h}_{q + p}^{( k ) *} ( {h}_{q}^{( k + 1 )} - {h}_{q}^{( k )} ) + \\ ( {h}_{q + p}^{( k + 1 ) *} - {h}_{q + p}^{( k ) *} ) ( ( P + Q - p ) {h}_{q}^{( k )} + p {h}_{q}^{( k + 1 )} ) +\end{matrix} \\ {i}^{2} {\sum }_{q = 0}^{L - 1 - p} ( {h}_{q + p}^{( k + 1 ) *} - {h}_{q + p}^{( k ) *} ) ( {h}_{q}^{( k + 1 )} - {h}_{q}^{( k )} )\end{matrix} )$$

$$\frac{1}{{( P + Q )}^{2}} ( \begin{matrix}{( P + Q )}^{2} {\sum }_{q = 0}^{L - 1 - p} {h}_{q + p}^{( k ) *} {h}_{q}^{( k )} + p ( P + Q ) {\sum }_{q = 0}^{L - 1 - p} {h}_{q + p}^{( k ) *} ( {h}_{q}^{( k + 1 )} - {h}_{q}^{( k )} ) + \\ i ( \begin{matrix}( P + Q ) {\sum }_{q = 0}^{L - 1 - p} {h}_{q + p}^{( k ) *} ( {h}_{q}^{( k + 1 )} - {h}_{q}^{( k )} ) + ( {h}_{q + p}^{( k + 1 ) *} - {h}_{q + p}^{( k ) *} ) {h}_{q}^{( k )} + \\ p {\sum }_{q = 0}^{L - 1 - p} ( {h}_{q + p}^{( k + 1 ) *} - {h}_{q + p}^{( k ) *} ) ( {h}_{q}^{( k + 1 )} - {h}_{q}^{( k )} )\end{matrix} ) + \\ {i}^{2} {\sum }_{q = 0}^{L - 1 - p} ( {h}_{q + p}^{( k + 1 ) *} - {h}_{q + p}^{( k ) *} ) ( {h}_{q}^{( k + 1 )} - {h}_{q}^{( k )} )\end{matrix} )$$

In a more condensed form:

$${B}_{m , m + p}^{start} = {F}_{k , p} + i ( {G}_{k , p} + i {H}_{k , p} ) \\ with : \\ δ {h}_{r}^{( k )} = {h}_{r}^{( k + 1 )} - {h}_{r}^{( k )} \\ \begin{matrix}{F}_{k , p} = {\sum }_{q = 0}^{L - 1 - p} {h}_{q + p}^{( k ) *} {h}_{q}^{( k )} + \frac{p}{P + Q} {\sum }_{q = 0}^{L - 1 - p} {h}_{q + p}^{( k ) *} δ {h}_{q}^{( k )} \\ {G}_{k , p} = \frac{1}{P + Q} {\sum }_{q = 0}^{L - 1 - p} {h}_{q + p}^{( k ) *} δ {h}_{q}^{( k )} + δ {h}_{q + p}^{( k ) *} {h}_{q}^{( k )} + \frac{p}{{( P + Q )}^{2}} {\sum }_{q = 0}^{L - 1 - p} δ {h}_{q + p}^{( k ) *} δ {h}_{q}^{( k )} \\ {H}_{k , p} = \frac{1}{{( P + Q )}^{2}} {\sum }_{q = 0}^{L - 1 - p} δ {h}_{q + p}^{( k ) *} δ {h}_{q}^{( k )}\end{matrix}$$

An identical reasoning would leading to writing the sum used at the end of a block

$${\sum }_{q = 0}^{L - 1 - p} {β}_{k , i , q + p}^{*} {β}_{k + 1 , i + p - P - Q , q}$$

in the form:

$${F}_{k , p}^{end} - ( P + Q - i ) ( {G}_{k , p}^{end} - ( P + Q - i ) {H}_{k , p}^{end} )$$

$$with : \\ \begin{matrix}{F}_{k , p}^{end} = {\sum }_{q = 0}^{L - 1 - p} {h}_{q + p}^{( k + 1 ) *} {h}_{q}^{( k + 1 )} + \frac{p}{P + Q} {\sum }_{q = 0}^{L - 1 - p} {h}_{q + p}^{( k + 1 ) *} δ {h}_{q}^{( k + 1 )} \\ {G}_{k , p}^{end} = \frac{1}{P + Q} {\sum }_{q = 0}^{L - 1 - p} {h}_{q + p}^{( k + 1 ) *} δ {h}_{q}^{( k + 1 )} + δ {h}_{q + p}^{( k ) *} {h}_{q}^{( k + 1 )} + \frac{p}{{( P + Q )}^{2}} {\sum }_{q = 0}^{L - 1 - p} δ {h}_{q + p}^{( k ) *} δ {h}_{q}^{( k + 1 )} \\ {H}_{k , p}^{end} = \frac{1}{{( P + Q )}^{2}} {\sum }_{q = 0}^{L - 1 - p} δ {h}_{q + p}^{( k ) *} δ {h}_{q}^{( k + 1 )}\end{matrix}$$

To recapitulate the above, this gives us:

-for k=0 . . . K−2

-for i=0 . . . P+Q−L

m=k(P+Q)+i

-for p=0 . . . L−1

coefficient of bₘ₊ₚ in the equation m given by

B_{m, m+p}^{start}

-for i=P+Q−L+1 . . . P+Q−1

m=k(P+Q)+i

-for p=0 . . . P+Q−1−i

coefficient of bₘ₊ₚ in the equation m given by

B_{m, m+p}^{start}

-for p=P+Q−i . . . L−1

coefficient of bₘ₊ₚ in the equation m given by

B_{m, m+p}^{end}

-for k=K−1

-for i=0 . . . P+Q−L

m=k (P+Q)+i

-for p=0 . . . L−1

coefficient of bₘ₊ₚ in the equation m given by

B_{m, m+p}^{start}

-for i=P+Q−L+1 . . . P+Q−1

m=k (P+Q)+i

-for p=0 . . . P+Q−1−i

coefficient of bₘ₊ₚ in the equation m given by

B_{m, m+p}^{start}

End of recapitulation.

The general appearance of the B (omitting the details) takes the following form (example for L=3, N=15, K=3 or P+Q=5):

$$B = \vert \begin{matrix}start & start & start & & & & & & & & & & & & \\ start & start & start & start & & & & & & & & & & & \\ start & start & start & start & start & & & & & & & & & & \\ & start & start & start & start & end & & & & & & & & & \\ & & start & start & start & end & end & & & & & & & & \\ & & & end & end & start & start & start & & & & & & & \\ & & & & end & start & start & start & start & & & & & & \\ & & & & & start & start & start & start & start & & & & & \\ & & & & & & start & start & start & start & end & & & & \\ & & & & & & & start & start & start & end & end & & & \\ & & & & & & & & end & end & start & start & start & & \\ & & & & & & & & & end & start & start & start & start & \\ & & & & & & & & & & start & start & start & start & start \\ & & & & & & & & & & & start & start & start & start \\ & & & & & & & & & & & & start & start & start\end{matrix} \vert$$

The rest of the operation (L-U decomposition, resolution, decision, etc) is known to those skilled in the art .

It must be noted that, while the above equations are more complex (to write) than in a case where a simple linear interpolation is taken to be sufficient for the entire frame, they represent equivalent computation power since there are no longer any terms to be computed and since the complexity of the expressions that give these equations (in terms of number of elementary operations) is equivalent.

However, it can be mentioned that the criterion of choice of the interpolators that gives the best results is deduced from the last step of the BDFE, in the manner explained here below.

This criterion gives the estimated signal-to-noise ratio for the frame after the execution of the BDFE algorithm which, it may be recalled, is aimed at determining the most probable values for the signal sent, taking into account the signal received and the impulse response of the channel estimated by the means explained here above.

To put it schematically, the final phase of the BDFE method is carried out in N steps (N is the number of unknown symbols sent out for the frame in the course of the modulation).

At the step n (n=0 . . . N−1), estimated values ê₀, ê₁, ê₂, . . . , êₙ₋₁ of the symbols sent are available.

The influence of the previous symbols sent out is then subtracted from the signal received rₙ, the impulse response of the channel being taken into account, to obtain a corrected value r′ₙ.

Then, in the current “constellation”, the point closest to r′ₙ (decision operation) is determined and it becomes the most probable (complex) value of the n^{th} symbol sent êₙ.

The difference between r′ₙ and êₙ is due to the noise (generally speaking) and the criterion of choice chosen may be the signal-to-noise ratio estimated for the frame as being the ratio between the mean power of the signal (the values of eₙ) and the mean power of the noise (mathematical expectation of the square of the modulus of the difference before decision):

$$Input Workspace TL4 \\ Date : 08 / 14 / 2003 Number : 10301821 Folder : 06$$

The higher this signal-to-noise ratio, the greater the extent to which the set of interpolators can be deemed to be suited to the current situation.

Given the fact that, if three sets of interpolators are rigorously tested to make a choice (the current set and its two neighbors), the BDFE algorithm must be iterated three times per frame to have an optimal level of performance.

However, in practice, it is not obligatory (except at the very beginning of the reception if this is absolutely indispensable) to perform these operations as frequently as this.

If (for example), the choice is made only every two frames, the BDFE algorithm does not need to be iterated more than (1+3)/2=2 times on an average per frame.

Another example: if the choice is made only every eight frames, the BDFE algorithm no longer needs to be iterated more than (1+1+ . . . +1+3)/8=1.25 times on an average per frame, representing a small increase in the computation power needed.

FIG. 7 gives a schematic view of the structure of a device according to the invention. The signal or signals, preconditioned after passage into a set of commonly used devices comprising adapted filters, an AGC (automatic gain control device, etc.) and all the devices enabling the preconditioning, is or are transmitted for example to a microprocessor 1 provided with the software designed to execute the different steps mentioned here above. The results obtained are then transmitted to a BDFE algorithm, 2, that can be used to obtain the most probable symbols sent, according to a method known to those skilled in the art.

What is claimed is:

1. A method for the equalization of data in a receiver after transmission in a channel, the received signal comprising one or more frames, a frame comprising at least one probe and one data block, wherein the method comprises at least one step in which at least one fictitious probe is determined in the data block by using at least one part of the probes available in the frames before and after the frame considered, a step for determining the intermediate impulse response or responses associated with the fictitious probe or probes and the combination of said intermediate impulse responses.

2. A method according to claim 1 wherein the fictitious probe is positioned substantially in the middle of a data block.

3. A method according to one of the claims 1 and 2 wherein several fictitious probes are positioned so as to be equally distributed in the data block or distributed so as to simplify the computations

4. A method according to one of the claims 1 to 3 wherein, for the computation of the fictitious probes, it is possible to use a total of M probes available in the vicinity of the data block considered with M preferably as an even number.

5. A method according to one of the claims 1 to 4 wherein the impulse responses associated with the fictitious probes are estimated for example by using the least error squares method.

6. A method according to one of the claims 1 to 5 wherein the fictitious probes to be positioned in the data block are determined by using interpolators and on the basis of one or more probes available before and/or after the data block.

7. A method according to claim 6 wherein the coefficients of the interpolators are chosen by minimizing the mean square error of the interpolation for a given maximum rotation of the impulse response between probes and for a signal-to-noise ratio value..

8. A method according to claim 7 wherein the coefficients of the interpolators are determined for several values of phase rotation A.

9. A device to equalize at least one signal that has traveled through a transmission channel, the receiver signal comprising one or more frames, a frame comprising at least one data block between two probes, wherein the device comprises at least one means receiving the signals and adapted to determining at least one fictitious probe in the data block by using at least one part of the available probes in the frames before and after the frame considered and a device adapted to determining the intermediate impulse response associated with the fictitious probe or probes and to combining said intermediate impulse responses.
